(19) United States
(12) Patent Application Publication
(10) Pub. No.: US 2015/0357180 A1
(43) Pub. Date: Dec. 10, 2015

(54) METHODS FOR CLEANING SEMICONDUCTOR SUBSTRATES

(71) Applicant: SunEdison Semiconductor Limited (UEN201334164H), Singapore (SG)

(72) Inventors: Sasha Joseph Kweskin, St. Louis, MO (US); Lara Short, O'Fallon, MO (US); Tracy M. Ragan, Warrenton, MO (US); James R. Capstick, Florissant, MO (US)

(73) Assignee: SUNEDISON SEMICONDUCTOR LIMITED (UEN201334164H), Singapore (SG)

(21) Appl. No.: 14/734,693

(22) Filed: Jun. 9, 2015

Related U.S. Application Data
(60) Provisional application No. 62/009,952, filed on Jun. 10, 2014.

(51) Int. Cl. H01L 21/02; H01L 21/306

(52) U.S. Cl. CPC H01L 21/0201; H01L 21/30625; H01L 21/02052; H01L 21/02082

(57) ABSTRACT

Methods for cleaning semiconductor substrates with cleaning baths including ammonium hydroxide, hydrogen peroxide and a non-ionic surfactant are disclosed. The methods may result in reduced re-adhesion of released particles during cleaning which produces cleaner substrates.

### CROSS-REFERENCE TO RELATED APPLICATIONS

The present application claims the benefit of U.S. Provisional Application No. 62/009,952, filed Jun. 10, 2014, which is incorporated herein by reference in its entirety.

### FIELD OF THE DISCLOSURE

The field of the disclosure relates to methods for cleaning semiconductor substrates and, in particular, methods for cleaning substrates that include reduced re-adhesion of particles.

### BACKGROUND

Semiconductor substrates may be produced by slicing the substrates from ingots of the semiconductor material. The substrates may be smoothed by use of chemical-mechanical planarization (CMP) processes in which the substrates are contacted with a chemical slurry and a polishing pad. Typically, the front and back surfaces of the substrates are smoothed concurrently in an initial “rough” polish followed by a “finish” or “mirror” polish in which the front surface of the substrate is more finely smoothed. After polishing, the substrates may be cleaned to remove residues and contaminants that result from the polish from the surfaces of the substrates.

A continuing need exists for improved processes for cleaning semiconductor substrates that allow multiple substrates to be cleaned concurrently at relatively close pitch in batch processes and which prevent re-adhesion of contaminants during the cleaning operation.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for smoothing semiconductor substrates. The substrates have a front surface, a back surface, a circumferential edge and a central axis. A surface of the substrates is polished while contacting the substrates with a chemical slurry. Polished substrates are stacked with the central axes of the substrates being generally aligned after stacking. A distance between adjacent substrates is less than about 10 mm. The polished substrates are immersed in a cleaning bath. The cleaning bath comprises ammonium hydroxide, hydrogen peroxide and a non-ionic surfactant to reduce re-adsorption of particles onto the substrates.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a graph of the critical micelle concentration of a non-ionic surfactant in the cleaning bath of Example 2;

FIG. 2 is a graph of the surface tension of the cleaning bath of Example 2 over time;

FIGS. 3-4 are defect maps of two single crystal silicon wafers immersed at half pitch in a conventional cleaning bath according to Example 4; and

FIGS. 5-6 are defect maps of two single crystal silicon wafers immersed at half pitch in a cleaning bath containing a non-ionic surfactant according to Example 4.

Corresponding reference characters indicate corresponding parts throughout the drawings.

### DETAILED DESCRIPTION

Provisions of the present disclosure relate to methods for cleaning semiconductor substrates and, in particular, methods that involve cleaning with a cleaning bath including ammonium hydroxide, hydrogen peroxide and a non-ionic surfactant. As compared to conventional methods, the methods of the present disclosure may reduce re-attachment of particles dislodged during the cleaning process thereby lowering defect counts. The methods may be well suited to reduce re-attachment of particles in batch immersion cleaning processes in which relatively high-diameter substrates (e.g., 300 mm and greater) are stacked at relatively tight pitch (e.g., half pitch) during cleaning, particularly in embodiments in which the substrates are stacked front-to-back (i.e., with the front surface of one substrate facing the back surface of another substrate). Compared to other surfactants, non-ionic surfactants are believed to have a reduced influence on the etch rate and on the zeta potential of the cleaning bath.

The semiconductor substrate may be composed of any material that may suitably be cleaned by SC-1 cleaning solutions. Structures which may be cleaned include, for example, silicon-on-insulator structures, epi-structures, heterostructures, single crystal silicon substrates and polysilicon substrates. These materials may comprise silicon, silicon carbide, sapphire, germanium, silicon germanium, gallium nitride, aluminum nitride, gallium arsenide, indium gallium arsenide, or quartz. In some embodiments, the semiconductor substrates are single crystal silicon wafers. Such wafers may be sliced from a single crystal ingot grown in accordance with conventional Czochralski crystal growing methods.

The semiconductor substrates that are cleaned according to embodiments of the present disclosure have a front surface, a back surface, a circumferential edge and a central axis. The semiconductor substrate may be any diameter suitable for use by those of skill in the art including, for example, about 200 mm, about 300 mm, greater than about 300 mm or even about 450 mm diameter substrates. In some embodiments, the structures have a diameter of about 300 mm or more.

In some embodiments, the semiconductor structures have been polished prior to cleaning. Polishing of wafers may be achieved using any polishing method known to those skilled in the art for reducing roughness and, for example, may be achieved by chemical-mechanical planarization (CMP). CMP typically involves the immersion of the wafer in an abrasive slurry and polishing of the wafer by a polymeric pad. Through a combination of chemical and mechanical means the surface of the wafer is smoothed. Typically, the polish is performed until a chemical and thermal steady state is achieved and until the wafers have achieved their targeted shape and flatness. The rough polish may be performed on a double-side polisher commercially available from Peter Wolters (e.g., AC2000 polisher; Rendsburg, Germany), Fujikoshi (Tokyo, Japan) or Speedfam (Kanagawa, Japan). Stock removal pads for silicon polishing are available from Psiloquest (Orlando, Fla.) or Dow Chemical Company (Midland, Mich.) and silica based slurries may be purchased from Dow, Cabot (Boston, Mass.), Nalco (Naperville, Ill.), Bayer MaterialScience (Leverkusen, Germany) or DA NanoMaterials (Tempe, Ariz.).

The rough polish may be applied to one surface of the wafer or, alternatively, to the front and back surfaces of the wafer. For example, the rough polish described above may be applied to both surfaces of the wafer through a double-side polish (DSP). A rough polish reduces the surface roughness of the wafer as measured with scan sizes of about 1 μm×about 1 μm to about 100 μm×about 100 μm to as low as about 1.5 Å and, more typically, to as low as about 1.9 Å. At shorter wavelengths a rough polish might reduce the surface roughness to less than about 2 Å as measured by scan sizes of about 0.1 μm×about 0.1 μm to about 1 μm×about 1 μm.

After the rough polish, the structure may be finished polished. The finish polish may be performed on commercially available polishers available from Speedfam (Kanagawa, Japan), Applied Materials, Inc. (Santa Clara, Calif.), LAM PLAN Industries Ltd. (Sevenoaks, United Kingdom), Dow Chemical Company (Midland, Mich.) and Strasbaugh (San Luis, Calif.). Polishing pads and slurries may be purchased from Fujimi Corporation (Tualatin, Oreg.), Nitta Haas, Inc. (Osaka, Japan) and Cabot Microelectronics Corporation (Aurora, Ill.).

The finish polish reduces the surface roughness of the wafer from the level obtained by rough polishing to about 1.7 Å to about 1.0 Å as measured by scan sizes of about 1 μm×about 1 μm to about 30 μm×about 30 μm. Typically the finish polish is only applied to the front surface of the wafer; however the finish polish may be applied to both surfaces without departing from the scope of the present disclosure. In embodiments in which the finish polish is not applied to the back surface of the substrate, the surface roughness of the front surface is generally less than the surface roughness of the back surface after finish polishing.

According to embodiments of the present disclosure, after polishing the substrates to be cleaned are fully immersed in a cleaning bath. The substrates are generally arranged in the bath such that the central axes of the substrates are aligned. The substrates may be arranged in a cassette that is immersed in the cleaning bath. In other embodiments, a cassetteless system is used and the substrates are lowered into the bath and secured by rods. Typically the substrates are robotically loaded into the cassette and/or cleaning bath; however, manual loading may also be performed.

In either a system using a cassette or a cassetteless system, a plurality of semiconductor substrates are immersed in the cleaning bath. In various embodiments at least about 2 substrates, at least about 5 substrates, at least about 15 substrates or at least about 30 substrates are immersed in the cleaning bath (e.g., from about 2 to about 50, from about 5 to about 50 or from about 15 to about 50 substrates). The components used to secure the wafers in the bath are typically high-purity parts such as PTFE, quartz or coated aluminum or stainless steel. Commercially available cleaning apparatus may be purchased from Echo Giken Co., LTD (Tokyo, Japan) and Akrion Systems LLC (Allentown, Pa.).

In some embodiments, the substrates are stacked at less than full pitch (i.e., less than about 10 mm between adjacent substrates) while immersed in the cleaning bath. For example, the substrates may be loaded at about half pitch (about 5 mm). In various embodiments of the present disclosure, the distance between substrates as stacked in the cleaning bath is less than about 8 mm, less than about 6 mm, from about 2 mm to about 10 mm or from about 2 mm to about 6 mm.

The substrates may be stacked such that the front surface of each substrate (excluding a substrate at the end of the stack) faces a back surface of another substrate (i.e., the substrates are stacked “front-to-back”). Alternatively, the substrates may be stacked such that a front surface of each substrate (excluding a substrate at the end of the stack if an odd number of substrates are loaded) faces a front surface of another substrate (i.e., the substrates are stacked “front-to-front and back-to-back”).

The substrates are fully immersed into a cleaning bath by lowering the cassette into the bath or, as in embodiments without a cassette, by lowering the substrates into the bath and securing each substrate in the bath. The bath comprises ammonium hydroxide and hydrogen peroxide which is typical of cleaning processes known in the art as “Standard Clean-1” (i.e., “SC-1”) or “RCA-1”. Such cleaning processes are typically used to remove organic residues and films from the surface of the substrates.

The amount of ammonium hydroxide in the cleaning bath may be at least about 0.01 wt %, at least about 0.05 wt % or at least about 0.1 wt % (e.g., from about 0.01 wt % to about 1 wt %, from about 0.01 wt % to about 0.5% or from about 0.05 wt % to about 0.5 wt %). The amount of hydrogen peroxide added may be at least about 0.01 wt %, at least about 0.1 wt %, at least about 0.5% or at least about 1 wt % (e.g., from about 0.01 wt % to about 10 wt %, from about 0.01 wt % to about 5 wt % or from about 0.05 wt % to about 5 wt %).

In addition to ammonium hydroxide and hydrogen peroxide, the cleaning bath contains a non-ionic surfactant. In some embodiments, the non-ionic surfactant comprises an ether group. In some embodiments the ether-based surfactant is a polyoxyalkylene alkyl ether. Commercially available ether-based surfactants include TRITON X-Series (Dow Chemical Company (Midland, Mich.)) and NCW1001 and NCW1002 (Wako Chemicals USA (Richmond, Va.)).

Preferably, the non-ionic surfactant is added at its critical micelle concentration (CMC) or below the CMC (e.g., less than about 50% of the CMC, less than about 25% or less than about 15% of the CMC). By reducing the concentration of the non-ionic surfactant to below the CMC, formation of bubbles large enough to reflect the acoustic field may be prevented. In some embodiments, the amount of non-ionic surfactant added is at least 0.0001 wt % of the cleaning bath or at least about 0.001 wt %, at least about 0.05 wt %, at least about 0.1 wt %, at least about 0.5 wt %, at least about 1 wt %, less than about 2 wt %, less than about 1 wt %, less than about 0.1 wt % or even less than about 0.01 wt % (e.g., from about 0.0001 wt % to about 2 wt %, from about 0.0001 wt % to about 0.01 wt %, from about 0.001 wt % to about 1 wt % or from about 0.05 wt % to about 1 wt %). It should be noted that the recited concentrations of ammonium hydroxide, hydrogen peroxide and non-ionic surfactant in the cleaning bath are exemplary and amounts outside of the stated ranges may be used without limitation. Preferably the added surfactant contains less than about 50 ppb of metal and less than about 500 particles per ml at a 0.3 μm/ml surfactant concentration.

A megasonic acoustic field may be applied to the cleaning bath during cleaning of the semiconductor substrates. Typical frequencies for megasonic cleaning may range from 750 kHz to about 1.5 MHz. Megasonic cleaning causes cavitation which promotes removal of particles from the surface of the substrates.

Typically the substrates are fully immersed in the cleaning solution. Generally and according to embodiments of the present disclosure, the substrates are not spun during cleaning in such immersion processes. In some embodiments, the substrates are not cleaned directly after a lapping process (i.e., a polish or other processing step is performed after lapping and before cleaning).

In various embodiments of the present disclosure, the substrates are immersed in the cleaning solution for at least about 30 seconds, at least about 1 minute, at least about 2 minutes or at least about 10 minutes or longer (e.g., from about 30 seconds to about 30 minutes or from about 30 seconds to about 20 minutes). The cleaning bath may be at room temperature (about 25° C.) or heated baths may be used (e.g., at least about 30° C., at least about 40° C., at least about 60° C., from about 30° C. to about 95° C. or from about 30° C. to about 80° C.)

In some embodiments, the polished substrates are immersed in a cleaning bath comprising hydrogen fluoride (HF) prior to immersion in the ammonium hydroxide and hydrogen peroxide cleaning bath. The HF bath may also include a non-ionic surfactant such as a non-ionic surfactant having an ether group (e.g., polyoxyalkylene alkyl ether) including the commercially available ether-based surfactants of TRITON X-Series (Dow Chemical Company (Midland, Mich.)) and NCW1001 and NCW1002 (Wako Chemicals USA (Richmond, Va.)). In some embodiments, the same surfactant is used in the HF cleaning bath as in the hydroxide and hydrogen peroxide cleaning bath.

The HF cleaning bath may include HF at a concentration from about 0.1 wt % to about 5 wt %. Preferably, the non-ionic surfactant is added at about its critical micelle concentration (CMC) (e.g., from about 90% to about 110% of the CMC). In some embodiments, the amount of non-ionic surfactant added is at least 0.0001 wt % of the cleaning bath or at least about 0.001 wt %, at least about 0.05 wt %, at least about 0.1 wt %, at least about 0.5 wt %, at least about 1 wt %, less than about 2 wt %, less than about 1 wt %, less than about 0.1 wt % or even less than about 0.01 wt % (e.g., from about 0.0001 wt % to about 2 wt %, from about 0.0001 wt % to about 0.1 wt %, from about 0.001 wt % to about 1 wt % or from about 0.05 wt % to about 1 wt %).

In some embodiments, the substrates are stacked at the same pitch as in the ammonium hydroxide and hydrogen peroxide cleaning bath. For example, the substrates may be stacked at less than full pitch (i.e., less than about 10 mm between adjacent substrates) while immersed in the HF cleaning bath. The substrates may be loaded at about half pitch (about 5 mm). In various embodiments of the present disclosure, the distance between substrates as stacked in the HF cleaning bath is less than about 8 mm, less than about 6 mm, from about 2 mm to about 10 mm or from about 2 mm to about 6 mm. The substrates may be stacked front-to-back or in an alternating front-to-front and back-to-back arrangement in the HF cleaning bath.

In embodiments in which an HF bath is used to clean the substrates, the substrates may be rinsed in deionized water (optionally including the non-ionic surfactant) before immersion in the ammonium hydroxide and hydrogen peroxide cleaning bath.

After immersion in the ammonium hydroxide, hydrogen peroxide cleaning solution, the wafers may be rinsed in a suitable solution such as deionized water. Preferably the rinse is relatively short compared to conventional methods to maintain a protective layer of surfactant. In various embodiments, the rinse may be less than about 6 minutes, less than about 4 minutes, less than about 2 minutes or even less than about 1 minute (e.g., from about 10 seconds to 6 minutes or from about 10 seconds to about 2 minutes).

### EXAMPLES

The processes of the present disclosure are further illustrated by the following Examples. These Examples should not be viewed in a limiting sense.

### Example 1

### Comparison of Defects in Wafers Loaded Back-to-Back Relative to Front-to-Back Loaded Wafers

Single crystal silicon wafers (300 mm) were double-side polished and finish polished. Prior to immersion in the SC-1 bath, the wafers were immersed in an ozone bath (>10 ppm ozone) for seven minutes. Two sets of 12 wafers were then immersed in a SC-1 cleaning bath containing ammonium hydroxide (approximately 0.2 to 0.8 wt %) and hydrogen peroxide (approximately 1-3 wt %). In one run of 12 wafers, the wafers were loaded face-to-face by interleaving the wafers. A second run of 12 wafers was loaded front-to-back per conventional practice. The wafers were separated at half pitch in the cleaning apparatus (Echo Giken Co., LTD (Tokyo, Japan)) during SC-1 cleaning.

The wafers were immersed for two minutes in the SC-1 baths at 65° C. After immersion in the SC-1 bath, the wafers were immersed in a SC-2 bath for 2 minutes.

The wafers of both sets were analyzed for defects larger than 37 nm. The median number of defects in the wafers treated in the face-to-face configuration was 30 and the median number of defects in the wafers cleaned in the front-to-back configuration in the same SC-1 solution was 58.

### Example 2

### Determination of the Critical Micelle Concentration of Non-Ionic Surfactants in SC-1 Cleaning Baths

The critical micelle concentration of a non-ionic surfactant having an ether group (NCW1002; Wako Chemicals USA (Richmond, Va.)) in a SC-1 cleaning bath) containing ammonium hydroxide (0.095 wt %) and hydrogen peroxide (1.53 wt %) was determined at 65° C. by use of a bubble tensiometer.

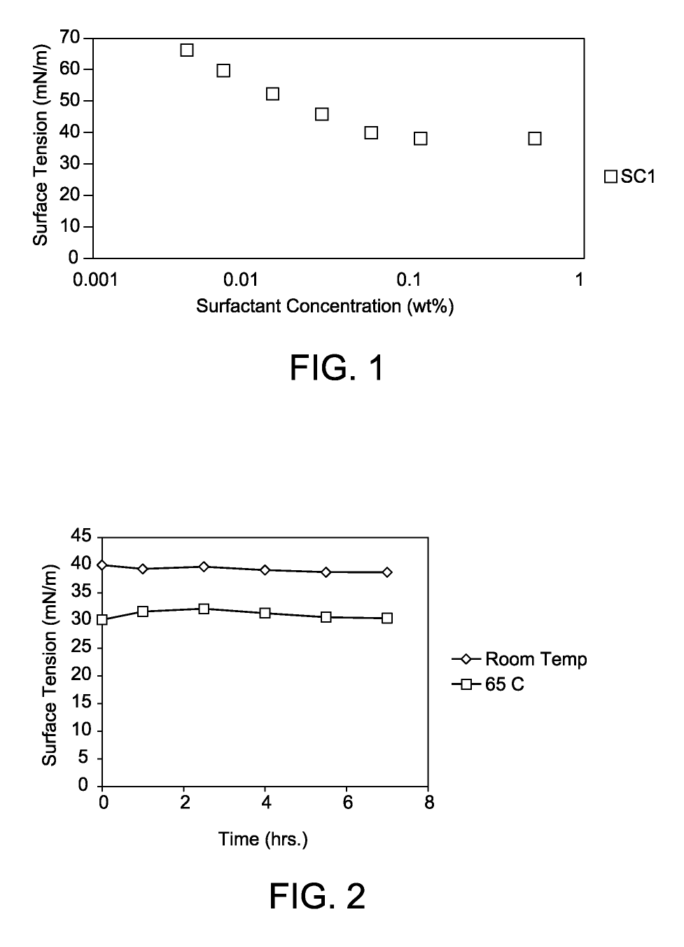

As shown in FIG. 1, the testing determined that the critical micelle concentration of the surfactant in the cleaning bath was 0.05 wt % surfactant, the amount specified by the manufacturer. This indicates that the ammonium hydroxide and hydrogen peroxide did not interact with the surfactant and affect the wetting ability of the surfactant.

### Example 3

### Surface Tension Stability

Surface tension stability of the cleaning solution of Example 2 at the critical micelle concentration of 0.05 wt % surfactant was determined over several hours. As shown in FIG. 2, the surface tension of the surfactant in the cleaning bath did not degrade over 7 hours at room temperature and at 65° C. indicating that the non-ionic surfactant is effective at long life.

### Example 4

### Defect and Surface Metal Reduction

Single crystal silicon wafers (200 mm) were double side polished and the front surface was finished polished. After polishing, the wafers were immersed at half pitch (about 5 mm) in a cleaning bath comprising ammonium hydroxide and hydrogen peroxide as in Example 1. A second bath additionally comprising a non-ionic surfactant comprising an ether group (NCW1002; Wako Chemicals USA (Richmond, Va.)) was also used to clean the set of wafers. The wafers were inspected on a KLA-Tencor SP1 inspection tool.

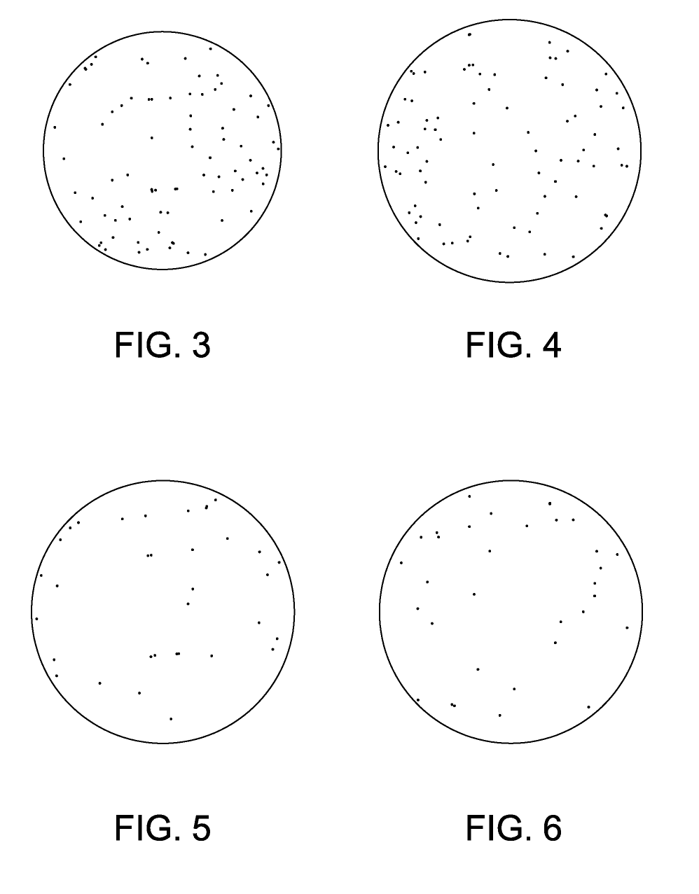

No addition of particles was observed at 55 nm for wafers cleaned in the cleaning bath including non-ionic surfactant. The laser light scattering (LLS) of defects greater than 55 nm is shown in FIG. 3-6. FIGS. 3-4 show defect maps for two wafers cleaned without surfactant in the cleaning bath and FIGS. 5-6 show defect maps for two wafers with a non-ionic surfactant present. As may be seen from FIGS. 3-6, the number of light scatterers was reduced when wafers were cleaned in a SC-1 cleaning bath containing non-ionic surfactant.

The copper content at the surface of the wafers was measured by inductively-coupled plasma mass spectrometry (ICPMS). The average copper content of the wafers cleaned without the non-ionic surfactant was 0.23×10¹⁰ atoms/cm². The average copper content of the wafers cleaned in the cleaning bath containing the surfactant was 0.09×10¹⁰ atoms/cm², more than a 50% reduction in copper.

### Example 5

### Reduction of Rinse Times

The cleaning bath containing non-ionic surfactant of Example 4 was used to treat wafers at half pitch. The rinse time in deionized water after the cleaning treatment was reduced from 378 seconds to 30 seconds for a batch of wafers. The average number of particles at 26 nm or more in size was reduced by 12% in wafers rinsed for 30 seconds.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for smoothing semiconductor substrates, the substrates having a front surface, a back surface, a circumferential edge and a central axis, the method comprising:
polishing a surface of the substrates while contacting the substrates with a chemical slurry;
stacking polished substrates, the central axes of the substrates being generally aligned after stacking, a distance between adjacent substrates being less than about 10 mm; and
immersing the polished substrates in a cleaning bath, the cleaning bath comprising ammonium hydroxide, hydrogen peroxide and a non-ionic surfactant to reduce re-adsorption of particles onto the substrates.

2. The method as set forth in claim 1 wherein the distance between adjacent substrates is less than about 8 mm.

3. The method as set forth in claim 1 wherein the distance between substrates is about 5 mm.

4. The method as set in claim 1 wherein the non-ionic surfactant comprises an ether group.

5. The method as set forth in claim 1 wherein the front surface and back surface each have a surface roughness, the surface roughness of the front surface being less than the surface roughness of the back surface, the substrates being stacked such that the front surface of a substrate faces a back surface of another substrate.

6. The method as set forth in claim 1 wherein the substrates have a diameter of at least about 300 mm.

7. The method as set forth in claim 1 wherein the substrates have a diameter of about 450 mm.

8. The method as set forth in claim 1 further comprising creating a megasonic acoustic field in the cleaning bath during immersion in the cleaning bath.

9. The method as set forth in claim 1 wherein the cleaning bath comprises surfactant in a concentration of less than about 0.01 wt %.

10. The method as set forth in claim 1 comprising polishing the front and back surfaces of the substrates while contacting the substrate with a chemical slurry.

11. The method as set forth in claim 1 wherein the front and back surfaces of the substrates are polished such that the front surface has a surface roughness less than a surface roughness of the back surface.

12. The method as set forth in claim 1 wherein the polished substrates are stacked into a cassette and the cassette and polished substrates are immersed in the cleaning bath.

13. The method as set forth in claim 1 wherein the polished substrates are immersed in the cleaning bath and secured by rods.

14. The method as set forth in claim 1 wherein the cleaning bath comprises the surfactant in a concentration less than a critical micelle concentration of the surfactant.

15. The method as set forth in claim 1 wherein the cleaning bath comprises the surfactant in a concentration less than about 50% of the critical micelle concentration of the surfactant.

16. The method as set forth in claim 1 wherein the cleaning bath comprises the surfactant in a concentration less than about 25% of the critical micelle concentration of the surfactant.

17. The method as set forth in claim 1 wherein the distance between adjacent substrates is less than about 6 mm.

18. The method as set forth in claim 1 wherein the cleaning bath comprises surfactant in a concentration from about 0.0001 wt % to about 0.01 wt %.

19. The method as set forth in claim 1 further comprising:
removing the polished substrates from the cleaning bath;
rinsing the wafer in deionized wafer after immersion in the cleaning bath for less than about 5 minutes.

20. The method as set forth in claim 1 further comprising immersing the polished substrates in a HF cleaning bath after stacking, the HF cleaning bath comprising HF and a non-ionic surfactant.
